(19) United States
(12) Patent Application Publication
(10) Pub. No.: US 2026/0082604 A1
(43) Pub. Date: Mar. 19, 2026

(54) LOW TEMPERATURE TUNNEL DIODE FOR NEGATIVE DIFFERENTIAL RESISTANCE

(71) Applicants: Abhishek A. Sharma, Portland, OR (US); Tahir Ghani, Portland, OR (US); Wilfred Gomes, Portland, OR (US)

(72) Inventors: Abhishek A. Sharma, Portland, OR (US); Tahir Ghani, Portland, OR (US); Wilfred Gomes, Portland, OR (US)

(21) Appl. No.: 18/887,248

(22) Filed: Sep. 17, 2024

(51) Int. Cl. H01L 29/88; H01L 23/473; H01L 27/07

(52) U.S. Cl. CPC H10D 8/70; H10D 84/811; H10W 40/47

(57) ABSTRACT

Highly-doped narrow bandgap materials, which may be nearly metallic at room temperature, may behave as semiconductor materials with high-mobility carriers when the carriers are cooled to a low temperature, e.g., below 250 Kelvin. In such low temperature environments, materials with narrower bandgaps may be used to form tunnel diodes. For example, one or both of the n-doped and p-doped regions may include a material with a bandgap of less than 0.5 eV. The materials used may have a high number of carriers, leading to relatively high currents, and better performance compared to previous room-temperature tunnel diodes using silicon or other standard semiconductor materials. For example, materials for forming tunnel diodes for operation at low temperature may be degenerately doped, with dopant concentrations of at least 10¹⁸ cm⁻³ or 10¹⁹ cm⁻³.

### BACKGROUND

Tunnel diodes, also referred to as Esaki diodes, include a heavily-doped p-n junction with a broken band gap. Conduction band electron states on the n-side of the junction may be substantially aligned with valence band hole states on the p-side of the junction. Tunnel diodes exhibit negative differential resistance in a portion of their operating range. When a tunnel diode is forward-biased past a threshold voltage, quantum mechanical tunneling occurs. The quantum tunneling effect gives rise to a region in the diode's voltage vs. current behavior in which an increase in forward voltage is accompanied by a decrease in forward current. This region is referred to as a negative differential resistance region.

### BRIEF DESCRIPTION OF THE DRAWINGS

Embodiments will be readily understood by the following detailed description in conjunction with the accompanying drawings. To facilitate this description, like reference numerals designate like structural elements.

Embodiments are illustrated by way of example, and not by way of limitation, in the figures of the accompanying drawings.

FIGS. 1A and 1B illustrate cross-sections of two example tunnel diodes, according to some embodiments of the present disclosure.

FIG. 2 illustrates an example I-V curve for negative differential resistance (NDR) devices disclosed herein, according to some embodiments of the present disclosure.

FIG. 3 illustrates an example horizontal implementation of a gated tunnel diode, according to some embodiments of the present disclosure.

FIG. 4 illustrates a first example vertical implementation of a tunnel diode, according to some embodiments of the present disclosure.

FIG. 5 illustrates a second example vertical implementation of a tunnel diode, according to some embodiments of the present disclosure.

FIGS. 6A-6C are three cross-sections illustrating a tunnel diode and transistor formed in a device plane, according to some embodiments of the present disclosure.

FIGS. 7A and 7B are top views of a wafer and dies that include one or more tunnel devices in accordance with any of the embodiments disclosed herein.

FIG. 8 is a cross-sectional side view of an IC device that may include one or more tunnel devices in accordance with any of the embodiments disclosed herein.

FIG. 9 is a cross-sectional side view of an IC device assembly that may include one or more tunnel devices in accordance with any of the embodiments disclosed herein.

FIG. 10 is a block diagram of an example computing device that may include one or tunnel devices in accordance with any of the embodiments disclosed herein.

FIG. 11 is a block diagram of an example processing device that includes one or more tunnel devices in accordance with any of the embodiments disclosed herein.

### DETAILED DESCRIPTION

### Overview

The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

A tunnel diode, also referred to as an Esaki diode, is a two-terminal device that is characterized by a current-voltage (I-V) curve with a region of negative differential resistance (NDR), or more generally, negative impedance. The I-V curve has an upper knee at the left and of the NDR region, and a lower knee at the right end of the NDR region; at voltages below the upper knee (e.g., moving leftward from the upper knee), the current trends downward with decreasing voltage, and at higher voltages (i.e., moving rightward from the lower knee), the current trends upwards with increasing voltage. A quantum tunneling effect may give rise the diode's voltage vs. current behavior within the NDR region.

In general, a diode is a two-terminal device that conducts current in one direction, referred to as the forward direction, while generally blocking current in the opposite direction, referred to as the reverse direction. In the forward direction, current enters through one terminal, which is called the anode, and leaves through the other terminal, which is called the cathode. When at least a minimum voltage, referred to as a forward voltage, is applied to the anode, this turns on the diode and current flows across the diode in the forward direction, from the anode to the cathode. Different types of materials may be used to form a diode. Many semiconductor diodes include a p-n junction, which is an interface between two types of semiconductor materials, p-type and n-type. Semiconductor diodes may include silicon, germanium, or other types of semiconductor materials.

In conductor and semiconductor materials, a charge carrier is a particle or quasiparticle that can move within the material, carrying a conductive charge and resulting in a net motion of particles through the material. In some semiconductors, the main charge carriers are electrons, while in others, the main charge carriers are electron holes (i.e., electron vacancies), generally referred to as holes. A semiconductor material or semiconductor region with holes as the primary charge carrier is referred to as p-type, and a semiconductor material or semiconductor region with electrons as the primary charge carrier is referred to as n-type.

A tunnel diode may have a heavily-doped p-n junction with a broken band gap, where conduction band electron states on the n-side of the junction are substantially aligned with valence band hole states on the p-side of the junction. As noted above, tunnel diodes exhibit negative differential resistance in a portion of their operating range. When a tunnel diode is forward-biased past a threshold voltage, quantum mechanical tunneling occurs. Quantum tunneling refers to probabilistic tunneling of an electron through the junction, or through one or more insulator layers, where the probabilistic tunneling is governed by quantum mechanics. The quantum tunneling effect gives rise to a region in the diode's voltage vs. current behavior, where an increase in forward voltage is accompanied by a decrease in forward current, i.e., an NDR region. More particularly, when the voltage increases past the threshold voltage, the electron states and empty valence band hole states on either side of the p-n junction become increasingly misaligned, and the current through the transistor drops. Beyond a second threshold voltage, the diode again begins to operate as a normal diode where electrons travel by conduction across the p-n junction, and no longer by tunneling through the p-n junction barrier.

Tunnel diodes have traditionally been fabricated using n-doped and p-doped silicon. Silicon has a band gap of around 1.14 electronvolts (eV). At room temperature, silicon-based tunnel diodes exhibit the tunneling effect, but the NDR region is relatively small, and the tunnelling current is fairly low.

Operating semiconductor devices, including tunnel diodes, at low temperatures can increase the amount of current flow. Furthermore, in a low temperature environment, materials with narrower bandgaps may be used to form tunnel diodes. For example, one or both of the n-doped and p-doped regions may include a material with a bandgap of less than 1 eV, less than 0.7 eV, less than 0.5 eV, or less than 0.3 eV. Highly-doped narrow bandgap materials, which may be nearly metallic at room temperature, may behave as semiconductor materials with high-mobility carriers when the carriers are cooled to a low temperature, e.g., below 250 Kelvin (K), below 200 K, below 100K, below 50K, below 25K, or below 10K. The materials described herein may have a high number of carriers, leading to relatively high currents, and better performance compared to previous room-temperature tunnel diodes using silicon or other standard semiconductor materials. For example, materials for forming tunnel diodes disclosed herein may be degenerately doped, with dopant concentrations of at least 10¹⁸ cm⁻³ or 10¹⁹ cm⁻³.

In some embodiments disclosed herein, tunnel diodes are arranged vertically through a device plane or transistor plane of an IC device, so that current flowing across the p-n junction moves in a direction perpendicular to the device plane. The tunnel diodes have an upper terminal and a lower terminal. The upper terminal may be formed over the wafer or other substrate on which the transistors are formed. The lower terminal may be formed on the back side or under side of the wafer or substrate over which the transistors are formed. For example, a semiconductor fin or pillar may be formed within the substrate or over the substrate, and highly-doped regions may be epitaxially grown over a top side and a bottom side of the fin or pillar. The substrate is thinned prior to forming the back-side epitaxial region and contact.

In other embodiments disclosed herein, tunnel diodes are arranged horizontally across a device plane or transistor plane of an IC device, so that current flows across the active region in a direction parallel to the device plane. The tunnel diodes have two terminals on either side of the active region; one or both terminals may be over or under the device plane (i.e., two backside contacts, two frontside contacts, or one backside contact and one frontside contact). A gate may be included to provide a bias voltage to the tunnel device.

An IC device includes various circuit elements, such as transistors, that are coupled together by metal interconnects. The circuit elements and metal interconnects may be formed in different layers. In particular, one or more layers of an IC device in which transistors and/or other IC components are implemented may be referred to as a “transistor layer,” “logic layer,” or “device layer”. Layers with conductive interconnects for providing electrical connectivity (e.g., in terms of signals and power) to the transistors and/or other devices of the transistor layer of the IC device may be referred to as a “metal layer,” “metallization layer,” or “interconnect layer”. For example, the device layer may be a front-end-of-line (FEOL) layer, while the metal layers may be back-end-of-line (BEOL) layers formed over the FEOL layer. A set of metallization layers are referred to as a metallization stack. In some embodiments disclosed herein, a first metallization stack is formed over a front side of the device layer, and a second metallization stack is formed over the back side of the IC device, i.e., on an opposite side of the device layer from the first metallization stack. The second metallization stack may be coupled to back-side contacts of the diodes and transistors.

Typically, an IC device includes a metallization stack, which is a collection of several metal layers, stacked above one another, in which different interconnects are provided. The interconnects include electrically conductive trenches, also referred to as lines, which provide connectivity across the layer, and electrically conductive vias (or, simply, “vias”) that provide electrical connectivity between different layers. In general, the term “trench” or “line” may be used to describe an electrically conductive element isolated by an insulator material (e.g., an insulator material typically comprising a low-k dielectric) that is provided in a plane parallel to the plane of an IC die/chip or a support structure over which an IC structure is provided, while the term “via” may be used to describe an electrically conductive element that interconnects two or more trenches of different levels of a metallization stack, or a component of the transistor layer and one or more trenches of a metallization layer. To that end, a via may be provided substantially perpendicularly to the plane of an IC die/chip or a support structure over which an IC structure is provided, and the via may interconnect two trenches in adjacent levels, two trenches in not adjacent levels, and/or a component of a transistor layer and a trench in adjacent or not adjacent layers. Sometimes, trenches and vias may be referred to as “metal trenches/tracks/lines/traces” and “metal vias”, respectively, to highlight the fact that these elements include electrically conductive materials such as, but not limited to, metals. Together, trenches and vias may be referred to as “interconnects,” “interconnect structures,” or “conductive structures,” where these terms may be used to describe any element formed of an electrically conductive material for providing electrical connectivity to/from one or more components associated with an IC or/and between various such components.

The tunnel diodes described herein may be implemented in combination with one or more components associated with an IC. In various embodiments, components associated with an IC include, for example, transistors, diodes, power sources, resistors, capacitors, inductors, sensors, transceivers, receivers, antennas, etc. Components associated with an IC may include those that are mounted on an IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

For purposes of explanation, specific numbers, materials and configurations are set forth in order to provide a thorough understanding of the illustrative implementations. However, it will be apparent to one skilled in the art that the present disclosure may be practiced without the specific details and/or that the present disclosure may be practiced with only some of the described aspects. In other instances, well known features are omitted or simplified in order not to obscure the illustrative implementations.

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. The meaning of “a,” “an,” and “the” include plural references. The meaning of “in” includes “in” and “on.”

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. The terms “substantially,” “close,” “approximately,” “near,” and “about,” generally refer to being within +/−20% of a target value, unless specified otherwise. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, various aspects of the illustrative implementations will be described using terms commonly employed by those skilled in the art to convey the substance of their work to others skilled in the art. For example, as used herein, a “logic state” of a ferroelectric memory cell refers to one of a finite number of states that the cell can have, e.g., logic states “1” and “0,” each state represented by a different polarization of the ferroelectric material of the cell. In another example, as used herein, a “READ” and “WRITE” memory access or operations refer to, respectively, determining/sensing a logic state of a memory cell and programming/setting a logic state of a memory cell. In other examples, the term “connected” means a direct electrical or magnetic connection between the things that are connected, without any intermediary devices, while the term “coupled” means either a direct electrical or magnetic connection between the things that are connected or an indirect connection through one or more passive or active intermediary devices. The term “circuit” means one or more passive and/or active components that are arranged to cooperate with one another to provide a desired function. In yet another example, a “high-k dielectric” refers to a material having a higher dielectric constant (k) than silicon oxide. The terms “oxide,” “carbide,” “nitride,” etc. refer to compounds containing, respectively, oxygen, carbon, nitrogen, etc.

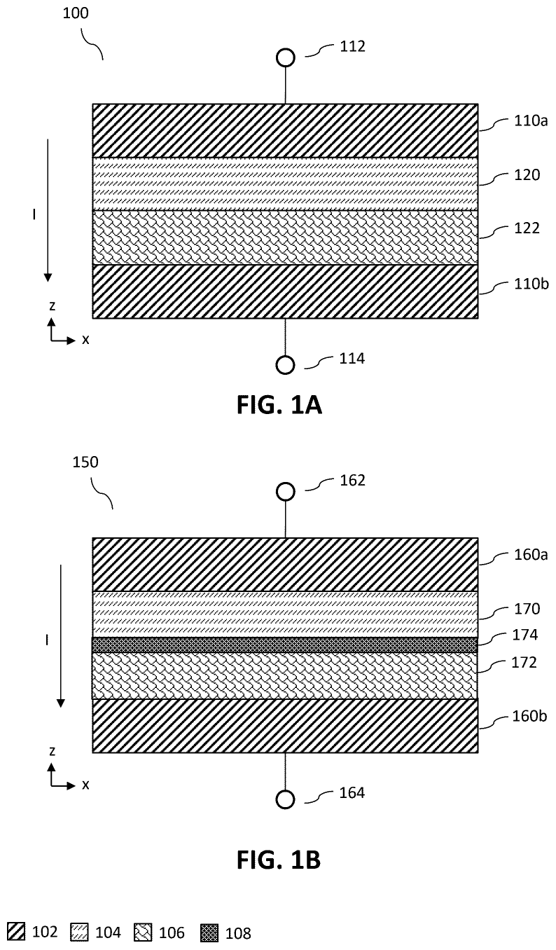

For convenience, if a collection of drawings designated with different letters are present, e.g., FIGS. 1A-1B, such a collection may be referred to herein without the letters, e.g., as “FIG. 1.”

### Example Tunnel Diodes

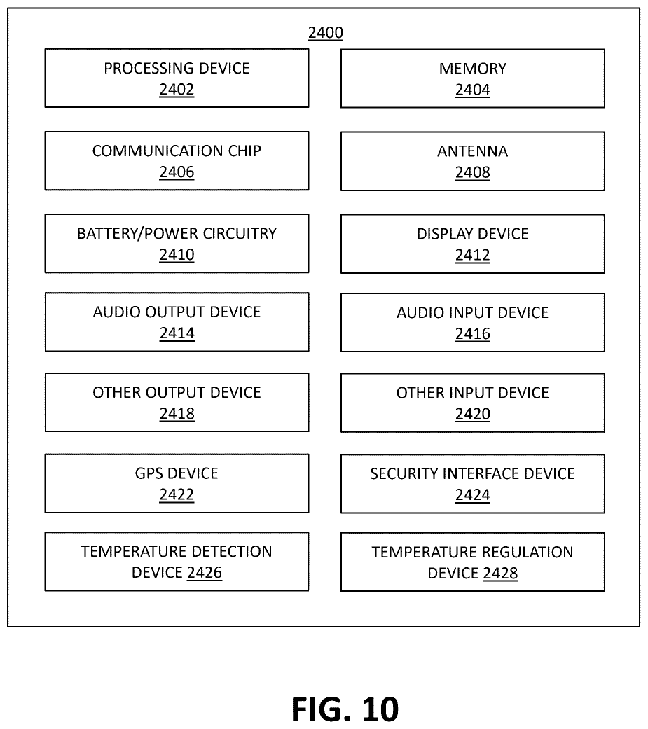

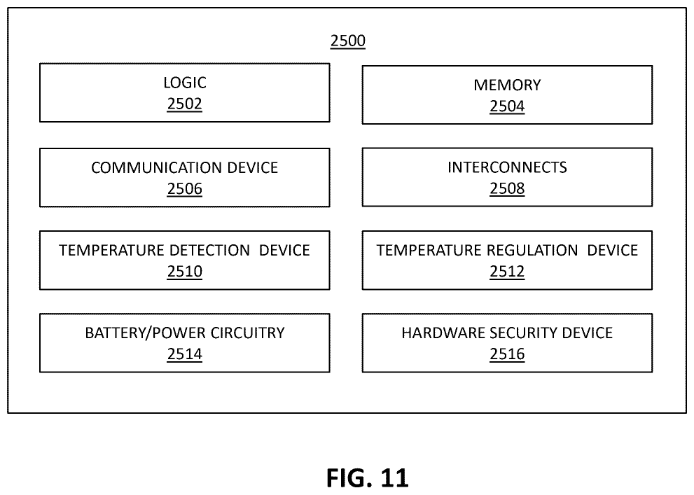

FIGS. 1A and 1B illustrate cross-sections of two example tunnel diodes, according to some embodiments of the present disclosure. One or more tunnel diodes 100 or 150 may be included in an IC device, e.g., an IC device operated at a low temperature, such as a system with a temperature regulation device as described with respect to FIGS. 10 and 11. A number of elements referred to in the description of FIGS. 1 and 3-6 with reference numerals are illustrated in these figures with different patterns, with a legend showing the correspondence between the reference numerals and patterns being provided at the bottom of the drawing pages. For example, the legend in FIG. 1 illustrates that FIG. 1 uses different patterns to show the conductor 102, a first doped semiconductor 104, a second doped semiconductor 106, and an insulator 108.

Turning first to FIG. 1A, a tunneling diode 100, also referred to as a diode 100, is illustrated. The diode 100 includes two layers 110a and 110b of the conductor 102, a first doped region 120 of the first doped semiconductor 104, and a second doped region 122 of the second doped semiconductor 106. The first doped region 120 of the first doped semiconductor 104 and the second doped region 122 of the second doped semiconductor 106 are between the two layers 110a and 110b of the conductor 102. In this example, the first doped region 120 is between the first metal layer 110a and the second doped region 122, and the second doped region 122 is between the first doped region 120 and the second metal layer 110b. The layers 110a and 110b are generally referred to as metal layers, and the doped regions 120 and 122 may be referred to as semiconductor layers or, jointly, as a semiconductor stack. Two terminals 112 and 114 are represented on the metal layers 110a and 110b; in this case, the terminal 112 is the anode, and the terminal 114 is the cathode. The forward direction, from the anode 112 to the cathode 114, is indicated by the arrow labelled I.

The conductor 102 may include one or more metals or metal alloys, with materials such as copper, ruthenium, palladium, platinum, cobalt, nickel, hafnium, zirconium, titanium, tantalum, and aluminum, tantalum nitride, tungsten, doped silicon, doped germanium, or alloys and mixtures of any of these. In some embodiments, the conductor 102 may include one or more electrically conductive alloys, oxides, or carbides of one or more metals.

At least one of the first doped semiconductor 104 and the second doped semiconductor 106 may include a narrow bandgap material, e.g., a material with a bandgap of less than 1 eV, less than 0.7 eV, less than 0.5 eV, or less than 0.3 eV. The first doped semiconductor 104 and/or the second doped semiconductor 106 may be highly doped, such that the material starts to behave like a metal rather than as a semiconductor. The first doped semiconductor 104 and/or the second doped semiconductor 106 may be degenerately doped. For example, the first doped semiconductor 104 and/or the second doped semiconductor 106 may have a dopant concentration of at least 10¹⁸ cm⁻³, at least 10¹⁹ cm⁻³, or at least 10²⁰ cm⁻³.

As noted above, highly-doped narrow bandgap materials, which may be nearly metallic at room temperature, may behave as semiconductor materials with high-mobility carriers when the carriers are cooled to a low temperature. For example, the diode 100 may be cooled to a temperature below 250K, below 200K, below 150K, below 100K, below 50K, below 25K, or below 10K. The temperature or temperature range of a device including the diode 100 may be based on a coolant used to cool the device, e.g., if liquid nitrogen is used, the operating temperature of the diode 100 may be between 77K and 250K (where 77K is the boiling point of nitrogen). As another example, if liquid helium is used, the operating temperature of the diode 100 may be as low as 4K.

In some embodiments, one of the doped semiconductors 104 and 106 includes indium, e.g., indium combined with one or more of arsenide (e.g., indium arsenide), oxygen (e.g., indium oxide), or nitrogen (e.g., indium nitride). An indium-based semiconductor is typically an n-type semiconductor material. In some embodiments, one of the doped semiconductors 104 and 106 includes tin, e.g., tin combined with one or more of arsenide (e.g., tin arsenide), oxygen (e.g., tin oxide), or nitrogen (e.g., tin nitride). Tin-based materials may be either p-type or n-type, depending on the structure, other materials, and/or dopants used. In some embodiments, one of the doped semiconductors 104 and 106 includes titanium, e.g., titanium combined with arsenic (e.g., titanium arsenide) or oxygen (e.g., titanium oxide). In some embodiments, one of the doped semiconductors 104 and 106 includes tantalum, e.g., tantalum combined with arsenic (e.g., tantalum arsenide) or oxygen (e.g., tantalum oxide).

In general, the semiconductor material at the current injection side (e.g., the anode 112) may have a higher mobility than the semiconductor material at the opposite end of the diode (e.g., the cathode 114). In some embodiments, the n-type material is at the anode side, and in other embodiments, the p-type material is at the cathode side. Furthermore, while certain materials are described as being n-type or p-type (e.g., based on their typical usage), certain semiconductor materials may be either n-type or p-type, depending on the dopant or dopants used.

In some embodiments, one of the first doped semiconductor 104 and second doped semiconductor 106 may include a monocrystalline semiconductor material, such as silicon or germanium. The first doped semiconductor 104 and/or second doped semiconductor 106 may be a semiconductor material that is suitable for depositing as a thin film. The first doped semiconductor 104 and/or second doped semiconductor 106 may include, for example, one or more of indium, gallium, tin, zinc, antimony, arsenic, copper, nickel, niobium, titanium, and oxygen. For example, the first doped semiconductor 104 and/or second doped semiconductor 106 may include gallium and arsenic (e.g., gallium arsenide) or gallium and antimony (e.g., gallium antimonide). In some embodiments, the first doped semiconductor 104 and/or second doped semiconductor 106 may be a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. Further examples include cobalt oxide, copper oxide, nickel oxide, niobium oxide, copper peroxide, indium telluride, molybdenite, molybdenum diselenide, tungsten diselenide, tungsten disulfide, N-or P-type amorphous or polycrystalline silicon, germanium, indium gallium arsenide, silicon germanium, gallium nitride, aluminum gallium nitride, indium phosphide, and black phosphorus, each of which may possibly be doped with one or more of gallium, indium, aluminum, fluorine, boron, phosphorus, arsenic, nitrogen, tantalum, tungsten, and magnesium, etc.

In some embodiments, one or more of the semiconductor materials may include a compound semiconductor with a first sub-lattice of at least one element from group III of the periodic table (e.g., Al, Ga, In), and a second sub-lattice of at least one element of group V of the periodic table (e.g., P, As, Sb). For some embodiments, one or more of the semiconductor materials may include a III-V material having a high electron mobility, such as, but not limited to InGaAs, InP, InSb, and InAs. For some such embodiments, one or more of the semiconductor materials may be a ternary III-V alloy, such as InGaAs, GaAsSb, InAsP, or InPSb. For some InₓGa₁₋ₓAs embodiments, the In content (x) may be between 0.6 and 0.9, and may advantageously be at least 0.7 (e.g., In_{0.7}Ga_{0.3}As). For other embodiments, one or more of the semiconductor materials may be a group IV material having a high hole mobility, such as, but not limited to Ge or a Ge-rich SiGe alloy. For some example embodiments, one or more of the semiconductor materials may have a Ge content between 0.6 and 0.9, and may be at least 0.7.

The first doped semiconductor 104 and second doped semiconductor 106 may have opposite dopant types, e.g., the first doped semiconductor 104 is a p-type material and the second doped semiconductor 106 is an n-type material. Both the first doped semiconductor 104 and the second doped semiconductor 106 may be heavily doped, e.g., with a dopant concentration of 1000 impurities per 10,000,000 semiconductor atoms. The dopant concentrations of the first doped semiconductor 104 and the second doped semiconductor 106 may be similar, e.g., one dopant concentration may be no more than two times the other, or the two dopant concentrations may be within the same order of magnitude. The dopant concentration within the first doped semiconductor 104 and the second doped semiconductor 106 may be on the order of 10¹⁹ to 10²⁰ dopants per cubic centimeter (i.e., 10¹⁹ to 10²⁰ cm⁻³). For example, the dopant concentrations in the first doped region 120 and second doped region 122 may be greater than 10¹⁸ cm⁻³, at least 10¹⁹ cm⁻³, between 10¹⁸ cm⁻³ and 10²⁰ cm⁻³, between 10¹⁹ cm⁻³ and 10²⁰ cm⁻³, or within some other range. By contrast, dopant concentration of a standard p-n junction diode may be around 1000 times less, e.g., on the order of 10¹⁶ to 10¹⁷ cm⁻³. The first doped region 120 and second doped region 122 may have thicknesses measured in the z-direction of, e.g., less than 25 nanometers, less than 15 nanometers (nm), less than 10 nm, less than 5 nm, less than 1 nm, or less than 500 Angstroms (Å).

The heavy doping results in a narrow depletion region, e.g., a depletion region that has a narrower width than a typical p-n junction. The depletion region may have a width on the order of 100 Å, e.g., less than 500 Å, less than 200 Å, less than 150 Å, less than 100 Å, between 50 and 200 Å, between 50 and 100 Å, or in some other range. The semiconductor stack (which, as noted above, includes the first doped region 120 and second doped region 122) may have a first thickness (measured in the z-direction in the orientation shown), and a second thickness of the depletion region (also measured in the z-direction) may have a thickness that is no greater than 60%, no greater than 50%, no greater than 40%, no greater than 30%, no greater than 25%, no greater than 20%, or no greater than 10% of the first thickness of the semiconductor stack. For example, the thickness of the depletion region may be between 10% and 60%, between 10% and 40%, between 25% and 50%, or within some other range of the thickness of the semiconductor stack.

The narrow depletion region produces a relatively high electrical current under a relatively low amount of voltage. Tunneling results from a direct flow of electrons across the narrow depletion region, from the n-doped side (e.g., the second doped region 122) to the p-doped side (e.g., the first doped region 120). In a p-n junction diode, both positive and negative ions form the depletion region. Due to these ions, an in-built electric potential or electric field is present in the depletion region. This electric field provides an electric force that is opposite the direction of externally applied voltage. As the width of the depletion layer reduces, charge carriers can easily cross the junction. Rather than kinetic energy moving charge carriers across the junction, the charge carriers punch through junction, an effect referred to as tunneling.

FIG. 1B illustrates a cross-section of a second example tunnel diode 150, according to some embodiments of the present disclosure. The tunnel diode 150 is similar to the tunnel diode 100, except that the diode 150 includes an insulator layer 174 between the n-type layer and the p-type layer. The diode 150 includes a first doped region 170 of the first doped semiconductor 104 and a second doped region 172 of the second doped semiconductor 106; these regions 170 and 172 are similar to the doped regions 120 and 122, respectively, of the diode 100. The insulator layer 174 is between the two doped regions 170 and 172. The diode 150 further includes a first metal layer 160a and a second metal layer 260b, which are similar to the metal layers 110a and 110b of the diode 100.

The insulator layer 174 includes an insulator 108. The insulator 108 may include oxygen (e.g., an insulating oxide) and/or nitrogen (e.g., an insulating nitride). The insulator 108 may include a metal in combination with the oxygen or nitrogen, e.g., hafnium, titanium, tantalum, or nickel, to form an insulator. For example, the insulator 108 may include hafnium oxide, titanium oxide, tantalum oxide, nickel oxide, or silicon nitride. The insulator layer 174 may be thin enough for tunneling to occur, e.g., less than 25 nanometers, less than 15 nanometers, less than 10 nanometers, less than 5 nanometers, less than 1 nanometer, or less than 500 Å.

While a single insulator layer 174 is illustrated in FIG. 1B, in some embodiments, the tunnel diode 150 includes two or more insulator layers in an insulator stack. The overall thickness of the insulator stack may be in the ranges described above. In some embodiments, instead of an insulator 108, a semiconductor layer may be included between the regions 170 and 172, e.g., a semiconductor material with a lower doping concentration than the first doped semiconductor 104 and the second doped semiconductor 106, or an undoped semiconductor material.

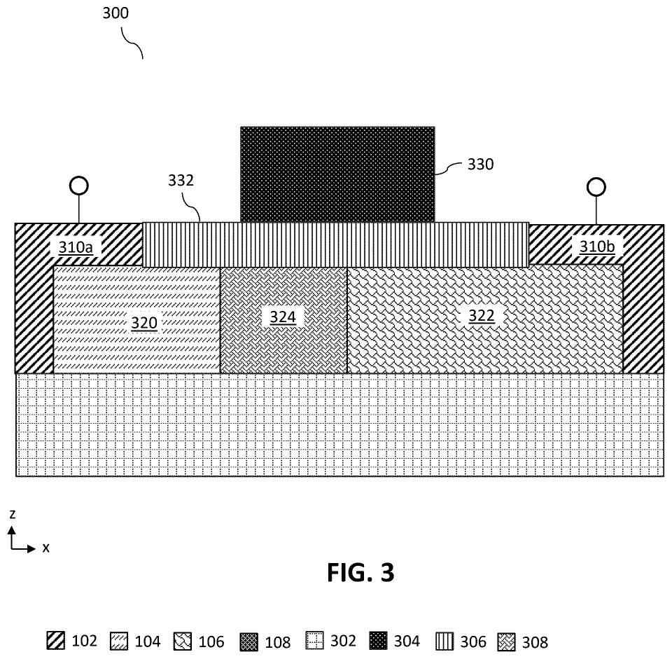

The illustrated tunnel diodes 100 and 150 are two-terminal devices, with an anode and a cathode. In some embodiments, a tunnel device further includes a gate coupled to a third terminal. This tunnel device may be referred to as a gated tunnel diode or a tunnel transistor. For example, a gate may be coupled to the first doped region 120 and/or second doped region 122 of the diode 100. The gate may be used to apply a voltage that alters the electric field within the depletion region. An example of a gated tunnel device is illustrated in FIG. 3, described below.

### Example I-V Curves for Tunnel Devices

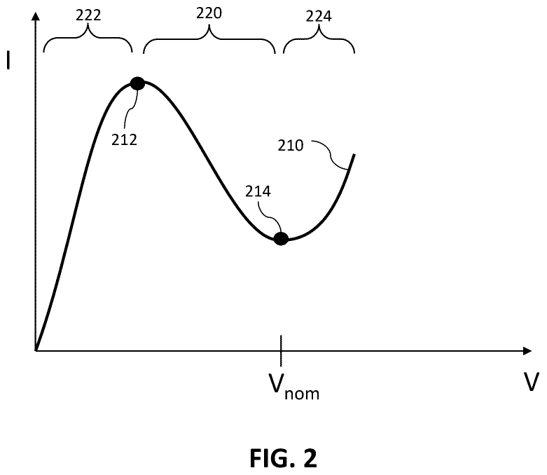

FIG. 2 illustrates an example I-V curve 210 for the tunnel devices disclosed herein, such as the tunnel diodes 100 and 150 described above. FIG. 2 illustrates voltage V along the x-axis and current I along the y-axis. In general, in an NDR device such as a tunnel diode, voltage is a single valued function of the current, but the current is a multivalued function of the voltage.

The I-V curve 210 includes a negative differential resistance region 220 between the points 212 and 214; in this region 220, the current decreases as the voltage increases, and the NDR device exhibits negative resistance. The voltage at the point 212 is a threshold voltage Vₜₕ for the NDR device. When the voltage difference across an NDR device increases beyond Vₜₕ, the current density starts to decrease. The current further decreases with an increase in the applied voltage. The point 214 represents the valley voltage or valley point, at which current begins increasing again in response to increasing voltage. The region 222 is a first positive differential resistance region, and the region 224 is a second positive differential resistance region. In the regions 222 and 224, increasing voltage causes the current to increase, as typical in a p-n junction.

In the region 222, when a forward voltage that is less than the built-in voltage of the depletion layer is applied to the tunnel diode, a forward current does not flow through the junction, but some electrons from the conduction band of the n-doped region (e.g., the second doped region 122 or 172) tunnel to the valence band in the p-doped region (e.g., the first doped region 120 or 170). This movement creates a small forward-biased tunnel current. Thus, when a small voltage is applied to the tunnel diode 100 or 150, the tunnel current starts to flow. As the amount of voltage applied to the tunnel diode is increased, the number of free electrons generated at the n-doped side (the second doped region 122 or 172) and the number of holes at the p-doped side (the first doped region 120 or 170) is also increased, leading to increased tunnel current. When the applied voltage increases further (e.g., past the threshold voltage point 212), there is a misalignment but still some overlap between the conduction band and the valence band, and the tunnel current decreases, resulting in the negative differential resistance of the region 220. When the applied voltage increases even further, past the valley point 214, the valence band and conduction band are completely misaligned, without any overlap; this causes the diode 100 or 150 to operate like a standard p-n junction diode within the region 224, with current increasing with voltage.

In some implementations, a tunnel device may be operated within the NDR region 220 to produce oscillations. For example, in the tunnel diode 100 or 150, sequential pulses traveling through the diode may produce a sustained oscillation at a particular oscillation frequency. The tunnel diode 100 or 150 may be arranged with one or more circuit elements (e.g., resistors, capacitors, and/or inductors) coupled to a voltage source to form a tunnel diode oscillator. Biasing a tunnel diode 100 or 150 in the NDR region 220 produces a voltage oscillation between the threshold voltage 212 and the valley voltage 214.

For example, as noted above, the tunnel diode 100 or 150 may be operated at a low temperature. In operation, the tunnel diode 100 or 150 may be cooled to a particular temperature or to a particular operating range, e.g., the tunnel diode 100 (or generally, a device that includes the tunnel diode 100) is cooled to a temperature below 200K or below 100K. An input voltage is then applied to the tunnel diode, where the input voltage biases the tunnel diode in the NDR region 220; in response, the tunnel diode produces an oscillating output signal, e.g., an oscillating voltage.

In some embodiments, the tunnel diodes 100 and 150 may be used to provide voltage regulation for an IC circuit, e.g., to regulate a supply line to a logic circuit within the IC device. For example, a tunnel diode may be biased at or near the voltage Vₙₒₘ, which corresponds to the voltage of the valley point 214. At the voltage Vₙₒₘ, a relatively low current passes through the tunnel diode. When a high load is applied to the power supply, the voltage output may drop. This condition is referred to as voltage droop, and may occur when many devices within the logic circuit are drawing power simultaneously, e.g., if many capacitors are being charged simultaneously. During the voltage droop, the tunnel diode moves into the NDR region 220. Specifically, moving leftward along the curve 210 from the valley point 214 causes the current passing through the tunnel diode to increase, and in turn, the current passing to the logic circuit to increase. This increased current can quickly satisfy the power need, enabling the voltage to return to the bias voltage Vₙₒₘ more quickly than if the tunnel diode is not included. A quick return to the Vₙₒₘ can enable smoother operation, e.g., greater stability and functionality of the logic circuit.

In a similar manner, if, rather than a voltage droop, there is a voltage surge (e.g., from the voltage source), the resistance across the tunnel diode increases in response to the increased voltage, leading to a relatively swift return (leftward along the curve 210 within the region 224) to the bias voltage Vₙₒₘ.

### Example Gated Tunnel Diode

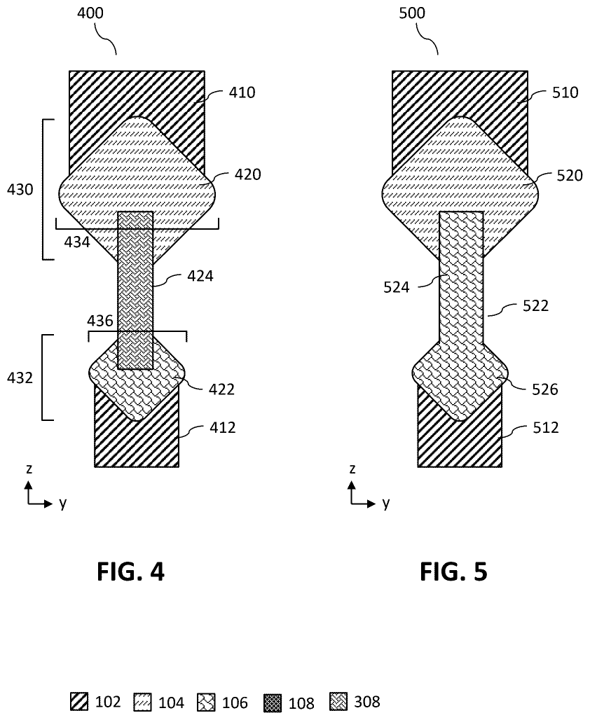

FIG. 3 illustrates an example implementation of a gated tunnel diode, according to some embodiments of the present disclosure. In this example, the tunnel diode is oriented horizontally, with current flowing in horizontal direction (e.g., parallel to a support structure or within on parallel to a device plane) across the tunnel diode. In other example implementations, the tunnel diode may be oriented vertically, e.g., as shown in FIGS. 4-6.

The diode 300 is formed over a support structure 302. The support structure 302 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. The support structure 302 may include one or more insulating layers, e.g., a buried oxide (BOX) layer. Although a few examples of materials from which the support structure 302 may be formed are described here, any material that may serve as a foundation upon which an IC device as described herein may be built falls within the spirit and scope of the present disclosure.

The diode 300 further includes a first doped region 320 of the first doped semiconductor 104 and a second doped region 322 of the second doped semiconductor 106. The first doped region 320 and the second region 322 are similar to the first doped region 120 and second doped region 122, except that while the first doped region 120 is stacked over the second doped region 122 in the vertical direction, the first doped region 320 and the second doped region 322 are arranged in a single layer over the support structure 302, at different horizontal positions in the layer over the support structure 302. In this example, the first doped region 320 and the second doped region 322 are at different positions along the x-direction.

In the example of FIG. 3, a region 324 is between the first doped region 320 and the second doped region 322. In some embodiments, the region 324 is an insulator, similar to the insulator layer 174 described with respect to FIG. 1B. In such embodiments, the material 308 forming the region 324 may be the insulator 108 described with respect to FIG. 1B. In other embodiments, the region 324 is a semiconductor region with a lower dopant concentration than the first doped region 320 and the second doped region 322. For example, the material 308 may be a semiconductor material (e.g., any of the materials described above with respect to the first doped semiconductor 104 and second doped semiconductor 106 material), where a dopant concentration of the material 308 is less than the dopant concentration of the first doped semiconductor 104 and less than the dopant concentration of the second doped semiconductor 106. For example, the material 308 may be a semiconductor with a dopant concentration of less than 10¹⁸ cm⁻³. The material 308 may be either an n-type semiconductor or a p-type semiconductor.

The region 324 may have a width measured in the x-direction that is less than 25 nanometers, less than 15 nanometers, less than 10 nanometers, less than 5 nanometers, less than 1 nanometer, or less than 500 Å. The depletion region of the p-n junction may be at least partially formed within the region 324. In some embodiments, the depletion region may extend beyond one or both edges of the region 324, e.g., the depletion region may extend partially into the first doped region 320 and/or the depletion region may extend partially into the second doped region 322.

A first terminal 310a is physically and electrically coupled to, and in this example, directly connected to the first doped region 320. Likewise, a second terminal 310b is physically and electrically coupled to, and in this example, directly connected to the second doped region 322. The terminals 310a and 310b include the conductor 102, described above. In this example, the first terminal 310a is formed over and around a portion of the first doped region 320, and the second terminal 310b is formed over and around a portion of the second doped region 322. Specifically, a first portion of the terminal 310a extends vertically along an outer side of the first doped region 320, and a second portion of the terminal 310a extends horizontally across a portion of a top side of the first doped region 320. Likewise, a first portion of the terminal 310b extends vertically along an outer side of the second doped region 322, and a second portion of the terminal 310b extends horizontally across a portion of a top side the second doped region 322. In other embodiments, the terminals 310 may have different shapes, e.g., the terminals 310 may only extend long the outer side walls of the doped regions, or the terminals 310 may be coupled only to the top sides of the doped regions.

A gate that includes a gate dielectric 332 and a gate electrode 330 is coupled to the semiconductor regions 320, 322, and/or 324 of the diode 300. In this example, the gate is formed over the layer with the regions 320, 322, and 324. Specifically, the gate dielectric 332 is between the terminals 310a and 310b, and the gate electrode 330 is over the gate dielectric 332. The gate electrode 330 includes an electrode material 304, and the gate dielectric 332 includes a dielectric material 306. The electrode material 304 may include at least one metal, such as hafnium, zirconium, titanium, tantalum, aluminum, alloys of these metals, carbides of these metals (e.g., hafnium carbide, zirconium carbide, titanium carbide, tantalum carbide, and aluminum carbide), ruthenium, palladium, platinum, cobalt, nickel, or a conductive metal oxide (e.g., ruthenium oxide). In some embodiments, the gate electrode 330 may include a stack of two or more metal layers, e.g., where one or more metal layers are work function metal layers and at least one metal layer is a fill metal layer.

In various embodiments, the dielectric material 306 may include one or more high-k dielectric materials and may include elements such as hafnium, silicon, oxygen, titanium, tantalum, lanthanum, aluminum, zirconium, barium, strontium, yttrium, lead, scandium, niobium, and zinc. Examples of high-k materials that may be used in the dielectric material 306 may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, the dielectric material 306 includes nitrogen, e.g., silicon nitride, silicon oxynitride, aluminum nitride, aluminum oxynitride, zinc nitride, hafnium nitride, etc. In some embodiments, the gate dielectric 332 may have a thickness between about 0.5 nanometers and 10 nanometers, including all values and ranges therein, e.g., between about 1 and 5 nanometers, or between about 1 and 3 nanometers.

The gate dielectric 332 is within the same layer as the second, upper portions of the terminals 310a and 310b, and the gate electrode 330 is over the gate dielectric 332. In other examples, at least a portion of the gate electrode 330 may extend beyond the tops of the terminals 310a and 310b (e.g., if the gate dielectric 332 is thicker than the terminals 310a and 310b), or at least a portion of the gate dielectric 332 may be in the same layer as the terminals 310a and 310b (e.g., if the gate dielectric 332 is thinner than the terminals 310a and 310b).

### Example Vertical Tunnel Diodes

FIG. 4 illustrates a first example vertical implementation of a tunnel diode, according to some embodiments of the present disclosure. The diode 400 is formed around a semiconductor fin 424. The semiconductor fin 424 includes the material 308 and corresponds to the region 324, which may be an insulator region (e.g., similar to the insulator layer 174) or a semiconductor region, as described with respect to FIG. 3. The diode 400 further includes a first doped region 420 and a second doped region 422, which are formed from the first and second doped semiconductors 104 and 106, respectively. The first doped region 420 corresponds to the first doped region 120 of the diode 100, and the second doped region 422 corresponds to the second doped region 122 of the diode 100. The diode 400 further includes a first contact 410 and a second contact 412. The first contact 410 corresponds to the first metal layer 110a of the diode 100, and the second contact 412 corresponds to the second metal layer 110b of the diode 100.

The semiconductor fin 424 is formed in or over a semiconductor substrate, e.g., a semiconductor wafer. The semiconductor wafer may have an initial thickness of, e.g., several hundred microns to over 1 millimeter. After frontside processing, a portion of the semiconductor wafer is thinned, either removing the semiconductor substrate entirely, or reducing the thickness of the semiconductor substrate to a few nanometers or a few tens of nanometers. While the semiconductor fin 424 is shown as having a rectangular cross-section in the y-z plane of the reference coordinate system shown, the semiconductor fin 424 may instead have a cross-section that is rounded or sloped at the “top” of the semiconductor fin 424, and the doped regions 420 and 422 may conform to this shape.

The semiconductor fin 424, as well as the first doped region 420 and first contact 410, are formed over the semiconductor substrate prior to thinning the semiconductor substrate. For example, after forming the semiconductor fin 424, the first doped region 420 is grown over the upper end of the semiconductor fin 424, and the first contact 410 is deposited over the first doped region 420. The semiconductor fin 424 may extend away from the semiconductor substrate and may be substantially perpendicular to the semiconductor substrate. The semiconductor fin 424 may have a height, a dimension measured in the direction of the z-axis of the reference coordinate system, which may, in some embodiments, be between about 20 and 350 nanometers, including all values and ranges therein (e.g. between about 40 and 150 nanometers, between about 75 and 250 nanometers, or between about 150 and 300 nanometers). In some embodiments, the semiconductor fin 424 may have a minimum height of 20 nanometers, 25 nanometers, 30 nanometers, 40 nanometers, or 50 nanometers.

After exposing the lower end of the fin 424 (e.g., by removing the semiconductor substrate), the second doped region 422 and second contact 412 are formed on the back side of the assembly. In some embodiments, the frontside elements of the diode 400 (i.e., the semiconductor fin 424, first doped region 420, and first contact 410) are formed, followed by a metallization stack that includes conductive structures coupled to the first contact 410. For example, the conductive structures may couple the first contact 410 to one or more transistor devices, which may be formed in the same layer as the diode 400. The assembly is then flipped, exposing the back side of the semiconductor substrate, which is thinned or removed. The second doped region 422 and second contact 412 may generally be formed using a similar process to the first doped region 420 and first contact 410.

The first doped region 420 and the second doped region 422 may be formed by epitaxial growth. For example, the first doped region 420 is epitaxially grown over or around an upper end of the semiconductor fin 424 (i.e., at a first end along the z-axis in the coordinate system shown), and the second doped region 422 is epitaxially grown over or around a lower end of the semiconductor fin 424 (i.e., at a second, opposite end along the z-axis in the coordinate system shown).

An epitaxial growth process can result in a generally diamond-shaped structure, as shown in the cross-section of FIG. 4, due to the crystallographic orientation of the underlying semiconductor material (e.g., the semiconductor fin 424 and, if present, the semiconductor substrate) and/or the growth process itself. In the example shown, the first doped region 420 and the second doped region 422 have rounded diamond shapes in cross-section; this shape is typical of many epitaxial growth processes around semiconductor fins. Specifically, a rounded diamond shape can result because, in an epitaxial deposition process, the growth tends to follow the crystal structure of the underlying structures, with a higher growth rate along certain crystallographic directions compared to others. While the illustrated diamond shape has sides of approximately equal length and rounded right-angles, in other embodiments, the rounded diamond shape may have some variation, e.g., upper sides may be longer than the lower sides (or vice versa), and the upper angle (i.e., the highest angle along the z-direction) may be acute, while the side angles are obtuse (or vice versa).

In this example, the doped regions 420 and 422 have different sizes. In particular, the first doped region 420 is larger than the second doped region 422. For example, in the cross-section of FIG. 4, the first doped region 420 has a larger cross-sectional area than the second doped region 422. Furthermore, the first doped region 420 has a height 430, measured in the z-direction, that is greater than a height 432 of the second doped region 422. The first doped region 420 also has a width 434, measured in the y-direction, that is greater than a width 436 of the second doped region 422. In some embodiments, the first doped region 420 also has a width measured in the x-direction (e.g., into the page in the orientation shown in FIG. 4) that is greater than a width of the second doped region 422 in the x-direction. In other embodiments, the doped region 422 may be larger than the doped region 420, or the doped regions 420 and 422 may have the same size or substantially the same size.

The width in the x-direction and/or y-direction of the doped regions 420 and 422 (e.g., the widths 434 and 436) may be in the range of 10 to 150 nanometers or a range therein, e.g., between 10 and 50 nanometers, or between 50 and 150 nanometers. The widths 434 and 436 of the doped regions 420 and 422 may each be at least 5 nanometers greater than a width of the semiconductor fin 424 (e.g., a width measured in the y-direction in the orientation shown). The widths 434 and 436 of the doped regions 420 and 422 may be between 5% larger (i.e., 1.05 times) and 10 times larger than a width of the semiconductor fin 424 or any range therein, e.g., between 5% and 50% larger, between 50% and 100% larger, between 1 and 2 times larger, between 2 and 5 times larger, or between 5 and 10 times larger. The width 434 of the first doped region 420 may be at least 5 nanometers, 10 nanometers, 20 nanometers, or 50 nanometers larger than the width 436 of the second doped region 422. The heights 430 and 432 of the doped regions 420 and 422 may be in the range of 5 to 200 nanometers or a range therein, e.g., between 5 and 50 nanometers, between 50 and 150 nanometers, or between 100 and 200 nanometers. The height 430 of the doped region 420 may be at least 5 nanometers, 10 nanometers, 20 nanometers, or 50 nanometers larger than the height 432 of the doped region 422.

The contacts 410 and 412 also have different sizes, with the first contact 410 being wider than the second contact 412. The increased contact area at the first end (e.g., between the first contact 410 and the first doped region 420) and the larger first doped region 420 may reduce contact resistance and improve current injection into the diode 400.

FIG. 5 is a cross-section illustrating a second example vertical tunnel diode, according to some embodiments of the present disclosure. FIG. 5 illustrates a diode 500 that is similar to the diode 400, except that the diode 500 includes a semiconductor fin 524 that includes the second doped semiconductor 106 rather than the material 308. The diode 500 includes a first doped region 520 and a second doped region 522, where the second doped region 522 includes both a fin portion 524 (corresponding to the same region as the semiconductor fin 424 of FIG. 4) and an epitaxial portion 526 (corresponding to the same region as the second doped region 422 of FIG. 4). The diode 500 includes a p-n junction without an insulator or lower-doped semiconductor material between the two doped regions 520 and 522. In other embodiments, the fin portion 524 may include the first doped semiconductor 104 rather than the second doped semiconductor 106. The diode 500 further includes a first doped region 520, which is similar to the first doped region 420, and a pair of contacts 510 and 512, which are similar to the first contact 410 and second contact 412 of FIG. 4.

The tunnel diode 400 or the tunnel diode 500 may include a gate stack (e.g., a gate dielectric and gate electrode) coupled to the semiconductor regions, e.g., around the fins 424 or 524 and, optionally, coupled to one or both of the epitaxial regions formed over and/or under the fins 424 and 524.

### Example Tunnel Diode in Device Plane

The tunnel diodes described herein, e.g., any of the diodes illustrated in FIGS. 3-5, may be included in a device plane or transistor plane of an IC device. In the case of a tunnel diode with one frontside contact and one backside contact (e.g., the diodes illustrated in FIGS. 4 and 5), the diode has one terminal over the plane, and the other terminal under the plane. In a horizontal tunnel diode with two frontside contacts (e.g., the diode 300 of FIG. 3), the diode has two terminals over the plane, and, in the case of a gated tunnel diode, the gate contact may also be over the plane. In other embodiments, one or more contacts to a horizontal tunnel diode may be backside contacts, where one or more terminals are under the plane.

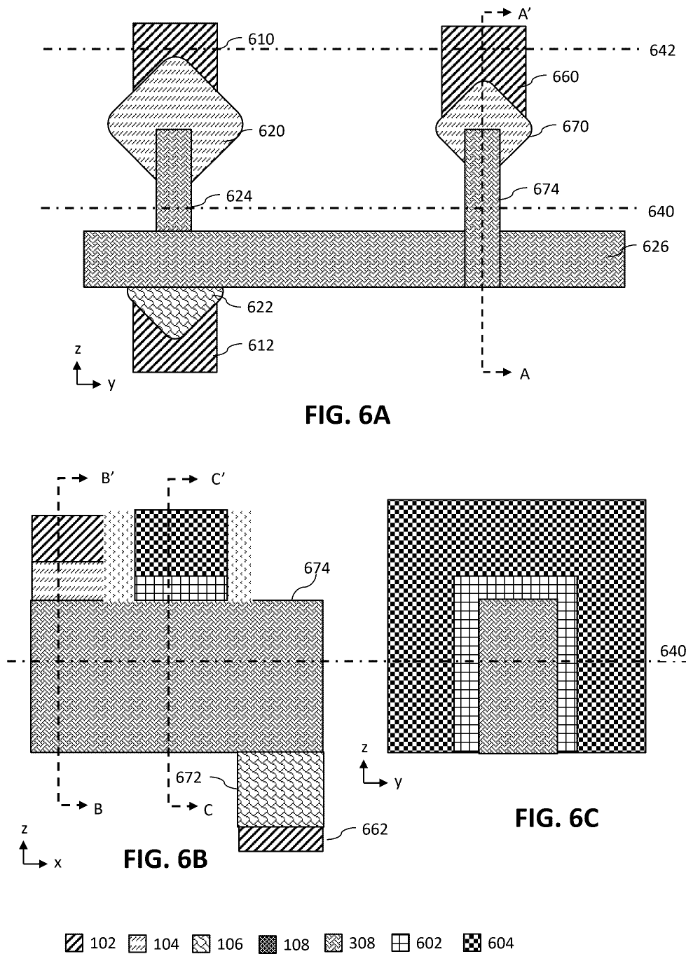

One or more other types of semiconductor devices, e.g., one or more transistors, can also be formed within the device plane. FIGS. 6A-6C are three cross-sections illustrating a tunnel diode and transistor formed in a device plane, according to some embodiments of the present disclosure. While FIG. 6 illustrates a vertical tunnel diode, in other embodiments, a horizontal tunnel diode, e.g., the tunnel diode 300, maybe in the device plane, e.g., in the same plane as the transistor device 650.

FIG. 6A illustrates a diode 600, which is similar to the diode 400. In this example, unlike the diode 400, a semiconductor fin 624 is formed over a semiconductor substrate 626. In this example, the semiconductor substrate 626 includes the same material 308 as the semiconductor fin 624, e.g., a semiconductor material. In other examples, the semiconductor fin 624 may be removed, e.g., as shown in FIG. 4. In other examples, the semiconductor fin 624 is formed from the first or second doped semiconductors 104 or 106, as described with respect to FIG. 5. The diode 600 includes a first doped region 620 and a second doped region 622, which are similar to the first doped region 420 and second doped region 422 of FIG. 4. The first doped region 620 is coupled to a contact 610, and the second doped region 622 is coupled to a contact 612. The contact 610 is similar to the first contact 410, and the second contact 612 is similar to the second contact 412.

FIG. 6A further includes a cross-section through a transistor device 650. FIG. 6B illustrates a cross-section of the transistor device 650 through the plane AA′. FIG. 6A is a cross-section through the plane BB′ in FIG. 6B, and FIG. 6C is a cross-section through the plane CC′ in FIG. 6B.

The transistor device 650 is a FinFET that includes a semiconductor fin 674, which is similar to the semiconductor fin 624. The semiconductor fin 674 is formed from the 308//. The semiconductor fin 674 extends upwards from a semiconductor substrate 626. The semiconductor substrate 626 may form a subfin for semiconductor fin 674 of the transistor 650. In this example, the semiconductor fin 674 may be longer than the semiconductor fin 624 in the x-direction.

The transistor device 650 includes a first source/drain (S/D) region 670, which is similar to the first doped region 620 of the diode 600, and a first S/D contact 660, which may be similar to the first contact 610 of the diode 600. For example, the first S/D region 670 and first S/D contact 660 may be fabricated in a same epitaxial deposition process as the first doped region 620 and first contact 610 of the diode 600. Alternatively, the first S/D region 670 and first S/D contact 660 may be fabricated in a separate, but similar, epitaxial deposition process as the first doped region 620 and first contact 610; for example, as shown in FIG. 6A, the first doped region 620 is larger than the first S/D region 670, indicating that the first doped region 620 may have been grown in a separate process from the first S/D region 670. In such embodiments, the first doped region 620 and the first S/D region 670 may include different materials, rather than the first S/D region 670 including the first doped semiconductor 104, as shown in FIG. 6. Alternatively, the first doped region 620 and the first S/D region 670 may have similar sizes and materials.

FIG. 6B further illustrates a second S/D region 672 and a second S/D contact 662. Here, the first S/D region 670 and first S/D contact 660 are formed over the front side of the transistor 650, e.g., over the device plane 640, while the second S/D region 672 and second contact 662 are formed on the back side of the transistor 650, e.g., under the device plane 640, described further below. The second S/D region 672 and second S/D contact 662 may be formed in a same process as the second doped region 622 and second contact 612 of the diode 600, or in different processes, as described with respect to the first S/D region 670.

A device plane 640 extends through the semiconductor devices 600 and 650. The device plane 640 extends in the x-and y-directions in the coordinate system shown. In this illustration, the device plane 640 extends through the semiconductor fin 674 of the transistor device 650 and the semiconductor fin 624 of the diode 600. A contact plane 642 is over the device plane 640; the contact plane 642 extends through the first contact 610 of the diode 600 and the first S/D contact 660 of the transistor 650. In this example, the first doped region 620 and first S/D region 670 are also over the device plane 640, but they are below the contact plane 642. The second doped region 622 and second contact 612 of the diode 600 are below the device plane 640, so that the first doped region 620 and first contact 610 are on an opposite side of the device plane 640 from the second doped region 622 and second contact 612. In different embodiments, different ones of the S/D regions/contacts may be formed over or under the device plane 640.

FIGS. 6B and 6C further illustrate the gate stack of the transistor 650. The gate stack includes a gate dielectric 602 that wraps around a central portion of the semiconductor fin 674, and a gate electrode 604 that wraps around the gate dielectric 602. If the diode 600 includes a gate, e.g., as shown in FIG. 3, the gate stack of the transistor 650 may be similar to the gate stack of the diode. For example, the gate stack may include the 330// and 332// described above.

The gate electrode 604 may include at least one P-type work function metal or N-type work function metal. For a PMOS transistor, metals that may be used for the gate electrode 604 may include, but are not limited to, ruthenium, palladium, platinum, cobalt, nickel, and conductive metal oxides (e.g., ruthenium oxide). For an NMOS transistor, metals that may be used for the gate electrode 604 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode 604 may include a stack of two or more metal layers, where one or more metal layers are WF metal layers and at least one metal layer is a fill metal layer.

In various embodiments, the gate dielectric 602 may include one or more high-k dielectric materials and may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric 602 may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, an annealing process may be carried out on the gate dielectric 602 during manufacture of the transistor 650 to improve the quality of the gate dielectric 602. In some embodiments, the gate dielectric 602 may have a thickness between about 0.5 nanometers and 3 nanometers, including all values and ranges therein, e.g., between about 1 and 3 nanometers, or between about 1 and 2 nanometers.

In some embodiments, the gate stack (i.e., the gate dielectric 602 and gate electrode 604) may be surrounded by a gate spacer, not shown in FIG. 6. Such a gate spacer would be configured to provide separation between the gate electrode 604 and the source/drain contacts of the transistor 650 and could be made of a low-k dielectric material, some examples of which have been provided above. A gate spacer may include pores or air gaps to further reduce its dielectric constant.

In the illustrated example, while the first contact 610, first doped region 620, second doped region 622, and second contact 612 are all aligned in the x-and y-directions, forming a vertical device where current travels vertically (e.g., in the z-direction) when the diode 600 is turned on, in the transistor 650, the first S/D contact 660 and first S/D region 670 are offset from the second S/D region 672 and second S/D contact 662 in the x-direction, so that when the transistor 650 is turned on, current travels horizontally in the x-direction through the transistor 650.

Furthermore, the fin length of the transistor 650 (e.g., a dimension of the semiconductor fin 674 in the x-direction, e.g., the horizontal dimension of the semiconductor fin 674 in FIG. 6B) may be longer than the fin length of the diode 600 (e.g., a dimension of the semiconductor fin 624 in the x-direction). This is because the semiconductor fin 674 of the transistor 650 extends under the gate stack, e.g., including the length of two S/D regions and the gate, whereas the semiconductor fin 624 of the diode 600 is cut by the FTI region (which, in a transistor device, is positioned where the gate stack is).

### Example Devices

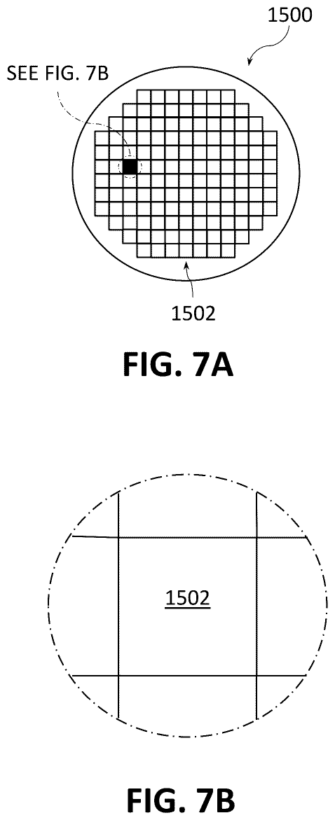

The tunnel devices, and circuits including tunnel devices, as disclosed herein may be included in any suitable electronic device. FIGS. 7-11 illustrate various examples of apparatuses that may include the one or more tunnel devices, e.g., tunnel diodes, disclosed herein, which may have been fabricated using the processes disclosed herein.

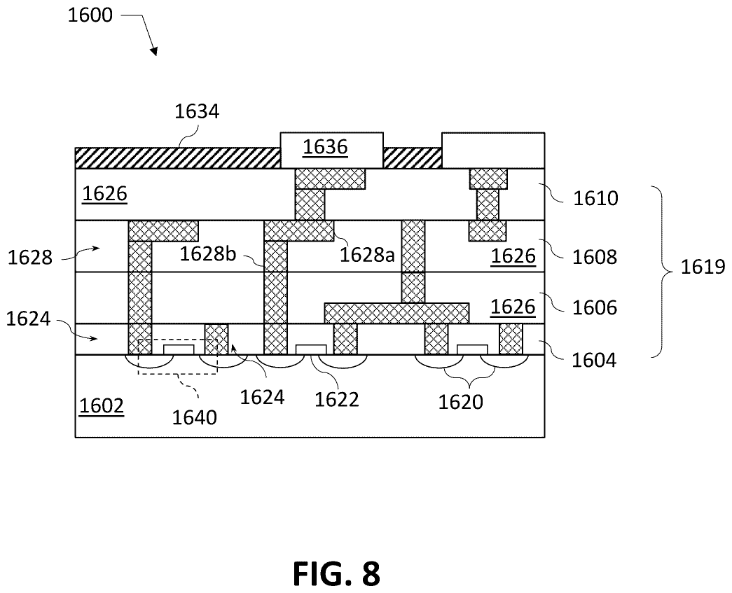

FIGS. 7A and 7B are top views of a wafer and dies that include one or more IC structures including one or more tunnel devices in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC structure (e.g., the IC structures as shown in any of FIGS. 1, 2, and 4-7, or any further embodiments of the IC structures described herein). After the fabrication of the semiconductor product is complete (e.g., after manufacture of one or more IC structures with one or more of the transistors as described herein, included in a particular electronic component, e.g., in a transistor or in a memory device), the wafer 1500 may undergo a singulation process in which each of the dies 1502 is separated from one another to provide discrete “chips” of the semiconductor product. In particular, devices that include one or more of the transistors as disclosed herein may take the form of the wafer 1500 (e.g., not singulated) or the form of the die 1502 (e.g., singulated). The die 1502 may include one or more transistors (e.g., one or more of the transistors 1640 of FIG. 8, discussed below) and/or supporting circuitry to route electrical signals to the transistors, as well as any other IC components (e.g., one or more of the non-planar transistors described herein). In some embodiments, the wafer 1500 or the die 1502 may include a memory device (e.g., an SRAM device), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 10) or other logic that is configured to store information in the memory devices or execute instructions stored in the memory array.

FIG. 8 is a cross-sectional side view of an IC device 1600 that may include one or more tunnel devices in accordance with any of the embodiments disclosed herein. The IC device 1600 may be formed on a substrate 1602 (e.g., the wafer 1500 of FIG. 7A) and may be included in a die (e.g., the die 1502 of FIG. 7B). The substrate 1602 may be any substrate as described herein. The substrate 1602 may be part of a singulated die (e.g., the dies 1502 of FIG. 7B) or a wafer (e.g., the wafer 1500 of FIG. 7A).

The IC device 1600 may include one or more device layers 1604 disposed on the substrate 1602. The device layer 1604 may include features of one or more transistors 1640 (e.g., metal-oxide-semiconductor field-effect transistors (MOSFETs)) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 8 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate electrode layer and a gate dielectric layer.

The gate electrode layer may be formed on the gate interconnect support layer and may consist of at least one P-type workfunction metal or N-type workfunction metal, depending on whether the transistor is to be a PMOS or an NMOS transistor, respectively. In some implementations, the gate electrode layer may consist of a stack of two or more metal layers, where one or more metal layers are workfunction metal layers and at least one metal layer is a fill metal layer. Further metal layers may be included for other purposes, such as a barrier layer or/and an adhesion layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 electron Volts (eV) and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, aluminum carbide, tungsten, tungsten carbide. An N-type metal layer will enable the formation of an NMOS gate electrode with a workfunction that is between about 3.9 eV and about 4.2 eV.

In some embodiments, when viewed as a cross-section of the transistor 1640 along the source-channel-drain direction, the gate electrode may be formed as a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may be implemented as a combination of U-shaped structures and planar, non-U-shaped structures. For example, the gate electrode may be implemented as one or more U-shaped metal layers formed atop one or more planar, non-U-shaped layers. In some embodiments, the gate electrode may consist of a V-shaped structure (e.g., when a fin of a FinFET transistor does not have a “flat”upper surface, but instead has a rounded peak).

Generally, the gate dielectric layer of a transistor 1640 may include one layer or a stack of layers, and the one or more layers may include silicon oxide, silicon dioxide, and/or a high-k dielectric material. The high-k dielectric material included in the gate dielectric layer of the transistor 1640 may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The IC device 1600 may include one or more tunnel devices at any suitable location in the IC device 1600.

The S/D regions 1620 may be formed within the substrate 1602 adjacent to the gate 1622 of each transistor 1640, using any suitable processes known in the art. For example, the S/D regions 1620 may be formed using either an implantation/diffusion process or a deposition process. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion implantation process. In the latter process, an epitaxial deposition process may provide material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620. In some embodiments, an etch process may be performed before the epitaxial deposition to create recesses in the substrate 1602 in which the material for the S/D regions 1620 is deposited.

Electrical signals, such as power and/or input/output (I/O) signals, may be routed to and/or from the transistors 1640 of the device layer 1604 through one or more interconnect layers disposed on the device layer 1604 (illustrated in FIG. 8 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form an ILD stack 1619 of the IC device 1600.

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 8). Although a particular number of interconnect layers 1606-1610 is depicted in FIG. 8, embodiments of the present disclosure include IC devices having more or fewer interconnect layers than depicted.

In some embodiments, the interconnect structures 1628 may include trench contact structures 1628a (sometimes referred to as “lines”) and/or via structures 1628b (sometimes referred to as “holes”) filled with an electrically conductive material such as a metal. The trench contact structures 1628a may be arranged to route electrical signals in a direction of a plane that is substantially parallel with a surface of the substrate 1602 upon which the device layer 1604 is formed. For example, the trench contact structures 1628a may route electrical signals in a direction in and out of the page from the perspective of FIG. 8. The via structures 1628b may be arranged to route electrical signals in a direction of a plane that is substantially perpendicular to the surface of the substrate 1602 upon which the device layer 1604 is formed. In some embodiments, the via structures 1628b may electrically couple trench contact structures 1628a of different interconnect layers 1606-1610 together.

The interconnect layers 1606-1610 may include a dielectric material 1626 disposed between the interconnect structures 1628, as shown in FIG. 8. The dielectric material 1626 may take the form of any of the embodiments of the dielectric material provided between the interconnects of the IC structures disclosed herein.

In some embodiments, the dielectric material 1626 disposed between the interconnect structures 1628 in different ones of the interconnect layers 1606-1610 may have different compositions. In other embodiments, the composition of the dielectric material 1626 between different interconnect layers 1606-1610 may be the same.

A first interconnect layer 1606 (referred to as Metal 1 or “M1”) may be formed directly on the device layer 1604. In some embodiments, the first interconnect layer 1606 may include trench contact structures 1628a and/or via structures 1628b, as shown. The trench contact structures 1628a of the first interconnect layer 1606 may be coupled with contacts (e.g., the S/D contacts 1624) of the device layer 1604.

A second interconnect layer 1608 (referred to as Metal 2 or “M2”) may be formed directly on the first interconnect layer 1606. In some embodiments, the second interconnect layer 1608 may include via structures 1628b to couple the trench contact structures 1628a of the second interconnect layer 1608 with the trench contact structures 1628a of the first interconnect layer 1606. Although the trench contact structures 1628a and the via structures 1628b are structurally delineated with a line within each interconnect layer (e.g., within the second interconnect layer 1608) for the sake of clarity, the trench contact structures 1628a and the via structures 1628b may be structurally and/or materially contiguous (e.g., simultaneously filled during a dual-damascene process) in some embodiments.

A third interconnect layer 1610 (referred to as Metal 3 or “M3”) (and additional interconnect layers, as desired) may be formed in succession on the second interconnect layer 1608 according to similar techniques and configurations described in connection with the second interconnect layer 1608 or the first interconnect layer 1606.

The IC device 1600 may include a solder resist material 1634 (e.g., polyimide or similar material) and one or more bond pads 1636 formed on the interconnect layers 1606-1610. The bond pads 1636 may be electrically coupled with the interconnect structures 1628 and configured to route the electrical signals of the transistor(s) 1640 to other external devices. For example, solder bonds may be formed on the one or more bond pads 1636 to mechanically and/or electrically couple a chip including the IC device 1600 with another component (e.g., a circuit board). The IC device 1600 may have other alternative configurations to route the electrical signals from the interconnect layers 1606-1610 than depicted in other embodiments. For example, the bond pads 1636 may be replaced by or may further include other analogous features (e.g., posts) that route the electrical signals to external components.

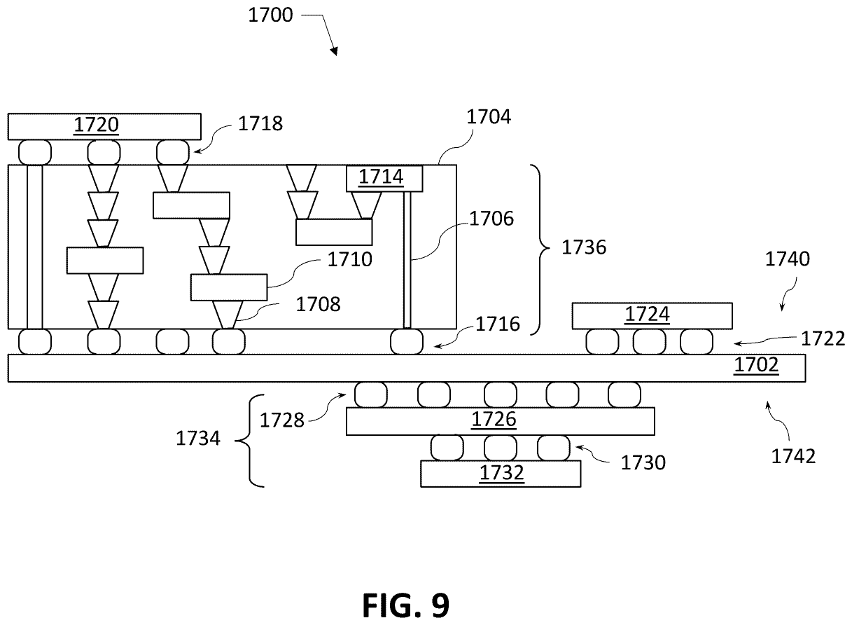

FIG. 9 is a cross-sectional side view of an IC device assembly 1700 that may include components having or being associated with (e.g., being electrically connected by means of) one or more tunnel devices in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. In particular, any suitable ones of the components of the IC device assembly 1700 may include one or more of the non-planar transistors disclosed herein.

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 9 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702 and may include solder balls (as shown in FIG. 9) male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 9, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 7B), an IC device (e.g., the IC device 1600 of FIG. 8), or any other suitable component. In some embodiments, the IC package 1720 may include one or more tunnel devices, as described herein. Generally, the interposer 1704 may spread a connection to a wider pitch or reroute a connection to a different connection. For example, the interposer 1704 may couple the IC package 1720 (e.g., a die) to a ball grid array (BGA) of the coupling components 1716 for coupling to the circuit board 1702. In the embodiment illustrated in FIG. 9, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

The interposer 1704 may be formed of an epoxy resin, a fiberglass-reinforced epoxy resin, a ceramic material, or a polymer material such as polyimide. In some implementations, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to TSVs 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 9 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 10 is a block diagram of an example computing device 2400 that may include one or more components including one or more tunnel devices in accordance with any of the embodiments disclosed herein. For example, any suitable ones of the components of the computing device 2400 may include a die (e.g., the die 1502 of FIG. 7) having one or more tunnel devices as described herein. Any one or more of the components of the computing device 2400 may include, or be included in, an IC device 1600 of FIG. 8 or an IC device assembly 1700 of FIG. 9.

A number of components are illustrated in FIG. 10 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single system-on-a-chip (SoC) die.

Additionally, in various embodiments, the computing device 2400 may not include one or more of the components illustrated in FIG. 10, but the computing device 2400 may include interface circuitry for coupling to the one or more components. For example, the computing device 2400 may not include a display device 2412, but may include display device interface circuitry (e.g., a connector and driver circuitry) to which a display device 2412 may be coupled. In another set of examples, the computing device 2400 may not include an audio input device 2416 or an audio output device 2414, but may include audio input or output device interface circuitry (e.g., connectors and supporting circuitry) to which an audio input device 2416 or audio output device 2414 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid state memory, and/or a hard drive. In some embodiments, the memory 2404 may include memory that shares a die with the processing device 2402. This memory may be used as cache memory and may include embedded DRAM (eDRAM) or spin transfer torque magnetic random-access memory (STT-MRAM).

In some embodiments, the computing device 2400 may include a communication chip 2406 (e.g., one or more communication chips). For example, the communication chip 2406 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2406 may implement any of a number of wireless standards or protocols, including but not limited to Institute for Electrical and Electronic Engineers (IEEE) standards including Wi-Fi (IEEE 1402.11 family), IEEE 1402.16 standards (e.g., IEEE 1402.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.16 standards. The communication chip 2406 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2406 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2406 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2406 may operate in accordance with other wireless protocols in other embodiments. The computing device 2400 may include an antenna 2408 to facilitate wireless communications and/or to receive other wireless communications (such as AM or FM radio transmissions).

In some embodiments, the communication chip 2406 may manage wired communications, such as electrical, optical, or any other suitable communication protocols (e.g., the Ethernet). As noted above, the communication chip 2406 may include multiple communication chips. For instance, a first communication chip 2406 may be dedicated to shorter-range wireless communications such as Wi-Fi or Bluetooth, and a second communication chip 2406 may be dedicated to longer-range wireless communications such as global positioning system (GPS), EDGE, GPRS, CDMA, WiMAX, LTE, EV-DO, or others. In some embodiments, a first communication chip 2406 may be dedicated to wireless communications, and a second communication chip 2406 may be dedicated to wired communications.

The computing device 2400 may include a battery/power circuitry 2410. The battery/power circuitry 2410 may include one or more energy storage devices (e.g., batteries or capacitors) and/or circuitry for coupling components of the computing device 2400 to an energy source separate from the computing device 2400 (e.g., AC line power).

The computing device 2400 may include a display device 2412 (or corresponding interface circuitry, as discussed above). The display device 2412 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2414 (or corresponding interface circuitry, as discussed above). The audio output device 2414 may include any device that generates an audible indicator, such as speakers, headsets, or earbuds, for example.

The computing device 2400 may include an audio input device 2416 (or corresponding interface circuitry, as discussed above). The audio input device 2416 may include any device that generates a signal representative of a sound, such as microphones, microphone arrays, or digital instruments (e.g., instruments having a musical instrument digital interface (MIDI) output).

The computing device 2400 may include an other output device 2418 (or corresponding interface circuitry, as discussed above). Examples of the other output device 2418 may include an audio codec, a video codec, a printer, a wired or wireless transmitter for providing information to other devices, or an additional storage device.

The computing device 2400 may include an other input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may include a GPS device 2422 (or corresponding interface circuitry, as discussed above). The GPS device 2422 may be in communication with a satellite-based system and may receive a location of the computing device 2400, as known in the art.

The computing device 2400 may include a security interface device 2424. The security interface device 2424 may include any device that provides security features for the computing device 2400 or for any individual components therein (e.g., for the processing device 2402 or for the memory 2404). Examples of security features may include authorization, access to digital certificates, access to items in keychains, etc. Examples of the security interface device 2424 may include a software firewall, a hardware firewall, an antivirus, a content filtering device, or an intrusion detection device.

In some embodiments, the computing device 2400 may include a temperature detection device 2426 and a temperature regulation device 2428.

The temperature detection device 2426 may include any device capable of determining temperatures of the computing device 2400 or of any individual components therein (e.g., temperatures of the processing device 2402 or of the memory 2404). In various embodiments, the temperature detection device 2426 may be configured to determine temperatures of an object (e.g., the computing device 2400, components of the computing device 2400, devices coupled to the computing device, etc.), temperatures of an environment (e.g., a data center that includes, is controlled by, or otherwise associated with the computing device 2400), and so on. The temperature detection device 2426 may include one or more temperature sensors. Different temperature sensors of the temperature detection device 2426 may have different locations within and around the computing device 2400. A temperature sensor may generate data (e.g., digital data) representing detected temperatures and provide the data to another device, e.g., to the temperature regulation device 2428, the processing device 2402, the memory 2404, etc. In some embodiments, a temperature sensor of the temperature detection device 2426 may be turned on or off, e.g., by the processing device 2402 or an external system. The temperature sensor detects temperatures when it is on and does not detect temperatures when it is off. In other embodiments, a temperature sensor of the temperature detection device 2426 may detect temperatures continuously and automatically or detect temperatures at predefined times or at times triggered by an event associated with the computing device 2400 or any components therein.

The temperature regulation device 2428 may include any device configured to change (e.g., decrease) temperatures, e.g., based on one or more target temperatures and/or based on temperature measurements performed by the temperature detection device 2426. A target temperature may be a preferred temperature. A target temperature may depend on a setting in which the computing device 2400 operates. In some embodiments, the target temperature may be 200 Kelvin degrees or lower. In some embodiments, the target temperature may be 20 Kelvin degrees or lower, or 5 Kelvin degrees or lower. Target temperatures for different objects and different environments of, or associated with, the computing device 2400 can be different. In some embodiments, cooling provided by the temperature regulation device 2428 may be a multi-stage process with temperatures ranging from room temperature to 4K or lower.

In some embodiments, the temperature regulation device 2428 may include one or more cooling devices. Different cooling device may have different locations within and around the computing device 2400. A cooling device of the temperature regulation device 2428 may be associated with one or more temperature sensors of the temperature detection device 2426 and may be configured to operate based on temperatures detected the temperature sensors. For instance, a cooling device may be configured to determine whether a detected ambient temperature is above the target temperature or whether the detected ambient temperature is higher than the target temperature by a predetermined value or determine whether any other temperature-related condition associated with the temperature of the computing device 2400 is satisfied. In response to determining that one or more temperature-related condition associated with the temperature of the computing device 2400 are satisfied (e.g., in response to determining that the detected ambient temperature is above the target temperature), a cooling device may trigger its cooling mechanism and start to decrease the ambient temperature. Otherwise, the cooling device does not trigger any cooling. A cooling device of the temperature regulation device 2428 may operate with various cooling mechanisms, such as evaporation cooling, radiation cooling, conduction cooling, convection cooling, other cooling mechanisms, or any combination thereof. A cooling device of the temperature regulation device 2428 may include a cooling agent, such as a water, oil, liquid nitrogen, liquid helium, etc. In some embodiments, the temperature regulation device 2428 may be, for example, a dilution refrigerator, a helium-3 refrigerator, or a liquid helium refrigerator. In some embodiments, the temperature regulation device 2428 or any portions thereof (e.g., one or more of the individual cooling devices) may be connected to the computing device 2400 in close proximity (e.g., less than about 1 meter) or may be provided in a separate enclosure where a dedicated heat exchanger (e.g., a compressor, a heating, ventilation, and air conditioning (HVAC) system, liquid helium, liquid nitrogen, etc.) may reside.

By maintaining the target temperatures, the energy consumption of the computing device 2400 (or components thereof) can be reduced, while the computing efficiency may be improved. For example, when the computing device 2400 (or components thereof) operates at lower temperatures, energy dissipation (e.g., heat dissipation) may be reduced. Further, energy consumed by semiconductor components (e.g., energy needed for switching transistors of any of the components of the computing device 2400) can also be reduced. Various semiconductor materials may have lower resistivity and/or higher mobility at lower temperatures. That way, the electrical current per unit supply voltage may be increased by lowering temperatures. Conversely, for the same current that would be needed, the supply voltage may be lowered by lowering temperatures. As energy corelates to the supply voltage, the energy consumption of the semiconductor components may lower too. In some implementations, the energy savings due to reducing heat dissipation and reducing energy consumed by semiconductor components of the computing device or components thereof may outweigh (sometimes significantly outweigh) the costs associated with energy needed for cooling.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

FIG. 11 is a block diagram of an example processing device 2500 that may include one or more IC devices with one or more tunnel devices in accordance with any of the embodiments disclosed herein. For example, any suitable ones of the components of the processing device 2500 may include a die (e.g., the die 1502 of FIG. 7) having one or more tunnel devices as described herein. Any one or more of the components of the processing device 2500 may include, or be included in, an IC device assembly 1700 (FIG. 8). Any one or more of the components of the processing device 2500 may include, or be included in, an IC device 1600 of FIG. 8 or an IC device assembly 1700 of FIG. 9. Any one or more of the components of the processing device 2500 may include, or be included in, a computing device 2400 of FIG. 10; for example, the processing device 2500 may be the processing device 2402 of the computing device 2400.

A number of components are illustrated in FIG. 11 as included in the processing device 2500, but any one or more of these components may be omitted or duplicated, as suitable for the application. In some embodiments, some or all of the components included in the processing device 2500 may be attached to one or more motherboards. In some embodiments, some or all of these components are fabricated on a single SoC die or coupled to a single support structure, e.g., to a single carrier substrate.

Additionally, in various embodiments, the processing device 2500 may not include one or more of the components illustrated in FIG. 11, but the processing device 2500 may include interface circuitry for coupling to the one or more components. For example, the processing device 2500 may not include a memory 2504, but may include display device interface circuitry (e.g., a connector and driver circuitry) to which a memory 2504 may be coupled.

The processing device 2500 may include logic circuitry 2502 (e.g., one or more circuits configured to implement logic/compute functionality). Examples of such circuits include ICs implementing one or more of input/output (I/O) functions, arithmetic operations, pipelining of data, etc.

In some embodiments, the logic circuitry 2502 may include one or more circuits responsible for read/write operations with respect to the data stored in the memory 2504. To that end, the logic circuitry 2502 may include one or more I/O ICs configured to control access to data stored in the memory 2504.

In some embodiments, the logic circuitry 2502 may include one or more high-performance compute dies, configured to perform various operations with respect to data stored in the memory 2504 (e.g., arithmetic and logic operations, pipelining of data from one or more memory dies of the memory 2504, and possibly also data from external devices/chips). In some embodiments, the logic circuitry 2502 may be configured to only control I/O access to data but not perform any operations on the data. In some embodiments, the logic circuitry 2502 may implement ICs configured to implement I/O control of data stored in the memory 2504, assemble data from the memory 2504 for transport (e.g., transport over a central bus) to devices/chips that are either internal or external to the processing device 2500, etc. In some embodiments, the logic circuitry 2502 may not be configured to perform any operations on the data besides I/O and assembling for transport to the memory 2504.

The processing device 2500 may include a memory 2504, which may include one or more ICs configure to implement memory circuitry (e.g., ICs implementing one or more of memory devices, memory arrays, control logic configured to control the memory devices and arrays, etc.). In some embodiments, the memory 2504 may be implemented substantially as described above with reference to the memory 2404 (FIG. 10). In some embodiments, the memory 2504 may be a designated device configured to provide storage functionality for the components of the processing device 2500 (i.e., local), while the memory 2404 may be configured to provide system-level storage functionality for the entire computing device 2400 (i.e., global). In some embodiments, the memory 2504 may include memory that shares a die with the logic circuitry 2502.

In some embodiments, the memory 2504 may include a flat memory (also sometimes referred to as a “flat hierarchy memory” or a “linear memory”) and, therefore, may also be referred to as a “basin memory.” As known in the art, a flat memory or a linear memory refers to a memory addressing paradigm in which memory may appear to the program as a single contiguous address space, where a processor can directly and linearly address all of the available memory locations without having to resort to memory segmentation or paging schemes. Thus, the memory implemented in the memory 2504 may be a memory that is not divided into hierarchical layer or levels in terms of access of its data.

In some embodiments, the memory 2504 may include a hierarchical memory. In this context, hierarchical memory refers to the concept of computer architecture where computer storage is separated into a hierarchy based on features of memory such as response time, complexity, capacity, performance, and controlling technology. Designing for high performance may require considering the restrictions of the memory hierarchy, i.e., the size and capabilities of each component. With hierarchical memory, each of the various memory components can be viewed as part of a hierarchy of memories (m₁, m₂, . . . mₙ) in which each member mᵢ is typically smaller and faster than the next highest member mᵢ₊₁ of the hierarchy. To limit waiting by higher levels, a lower level of a hierarchical memory structure may respond by filling a buffer and then signaling for activating the transfer. For example, in some embodiments, the hierarchical memory implemented in the memory 2504 may be separated into four major storage levels: 1) internal storage (e.g., processor registers and cache), 2) main memory (e.g., the system RAM and controller cards), and 3) on-line mass storage (e.g., secondary storage), and 4) off-line bulk storage (e.g., tertiary, and off-line storage). However, as the number of levels in the memory hierarchy and the performance at each level has increased over time and is likely to continue to increase in the future, this example hierarchical division provides only one non-limiting example of how the memory 2504 may be arranged.

The processing device 2500 may include a communication device 2506, which may be implemented substantially as described above with reference to the communication chip 2406 (FIG. 10). In some embodiments, the communication device 2506 may be a designated device configured to provide communication functionality for the components of the processing device 2500 (i.e., local), while the communication chip 2406 may be configured to provide system-level communication functionality for the entire computing device 2400 (i.e., global).

The processing device 2500 may include interconnects 2508, which may include any element or device that includes an electrically conductive material for providing electrical connectivity to one or more components of, or associated with, a processing device 2500 or/and between various such components. Examples of the interconnects 2508 include conductive lines/wires (also sometimes referred to as “lines” or “metal lines” or “trenches”) and conductive vias (also sometimes referred to as “vias” or “metal vias”), metallization stacks, redistribution layers, metal-insulator-metal (MIM) structures, etc.

The processing device 2500 may include a temperature detection device 2510 which may be implemented substantially as described above with reference to the temperature detection device 2426 of FIG. 10 but configured to determine temperatures on a more local scale, i.e., of the processing device 2500 of components thereof. In some embodiments, the temperature detection device 2510 may be a designated device configured to provide temperature detection functionality for the components of the processing device 2500 (i.e., local), while the temperature detection device 2426 may be configured to provide system-level temperature detection functionality for the entire computing device 2400 (i.e., global).

The processing device 2500 may include a temperature regulation device 2512 which may be implemented substantially as described above with reference to the temperature regulation device 2428 of FIG. 10 but configured to regulate temperatures on a more local scale, i.e., of the processing device 2500 of components thereof. In some embodiments, the temperature regulation device 2512 may be a designated device configured to provide temperature regulation functionality for the components of the processing device 2500 (i.e., local), while the temperature regulation device 2428 may be configured to provide system-level temperature regulation functionality for the entire computing device 2400 (i.e., global).

The processing device 2500 may include a battery/power circuitry 2514 which may be implemented substantially as described above with reference to the battery/power circuitry 2410 of FIG. 10. In some embodiments, the battery/power circuitry 2514 may be a designated device configured to provide battery/power functionality for the components of the processing device 2500 (i.e., local), while the battery/power circuitry 2410 may be configured to provide system-level battery/power functionality for the entire computing device 2400 (i.e., global).

The processing device 2500 may include a hardware security device 2516 which may be implemented substantially as described above with reference to the security interface device 2424 of FIG. 10. In some embodiments, the hardware security device 2516 may be a physical computing device configured to safeguard and manage digital keys, perform encryption and decryption functions for digital signatures, authentication, and other cryptographic functions. In some embodiments, the hardware security device 2516 may include one or more secure cryptoprocessors chips.

The above description of illustrated implementations of the disclosure, including what is described in the Abstract, is not intended to be exhaustive or to limit the disclosure to the precise forms disclosed. Unless specified otherwise, in various embodiments, features described with respect to one of the drawings may be combined with those described with respect to other drawings.

### SELECT EXAMPLES

The following paragraphs provide various examples of the embodiments disclosed herein.

Example 1 provides a system including a cooling device; and an integrated circuit (IC) device including a diode, the diode including an n-type region having a first dopant concentration greater than 10¹⁸ cm⁻³; and a p-type region coupled to the n-type region, the p-type region having a second dopant concentration greater than 10¹⁸ cm⁻³.

Example 2 provides the system of example 1, where the cooling device includes a direct refrigerant.

Example 3 provides the system of example 1 or 2, where the cooling device includes a heat exchanger.

Example 4 provides the system of any of examples 1-3, where the cooling device is on a cooling package, and the IC device is on a separate package from the cooling package.

Example 5 provides the system of any of examples 1-4, where the cooling device is configured to cool the IC device to a temperature of 77-250 Kelvin.

Example 6 provides the system of any of examples 1-5, where at least one of the n-type region and the p-type region includes a material having a band gap of less than 0.5 electronvolts (eV).

Example 7 provides the system of example 6, where materials in the n-type region and the p-type region each have a band gap of less than 0.5 electronvolts (eV).

Example 8 provides the system of any of examples 1-7, where the first dopant concentration is within an order of magnitude of the second dopant concentration.

Example 9 provides the system of any of examples 1-8, where the n-type region includes indium.

Example 10 provides the system of example 9, where the n-type region further includes one of oxygen, nitrogen, or arsenic.

Example 11 provides the system of any of examples 1-8, where the n-type region or the p-type region includes tin.

Example 12 provides the system of example 11, where the n-type region or the p-type region further includes one of oxygen, nitrogen, or arsenic.

Example 13 provides the system of any of examples 1-8, where the n-type region or the p-type region includes arsenic and one of titanium or tantalum.

Example 14 provides a device including an n-type region having a first dopant concentration greater than 10¹⁸ cm⁻³; and a p-type region coupled to the n-type region, the p-type region having a second dopant concentration greater than 10¹⁸ cm⁻³; where at least one of the n-type region and the p-type region includes a material having a band gap of less than 0.5 electronvolts (eV).

Example 15 provides the device of example 14, the device including a depletion region at a junction of the n-type region and the p-type region, where the n-type region and the p-type region form a semiconductor region having a first thickness, and the depletion region has a second thickness no more than 50% the first thickness.

Example 16 provides the device of example 14 or 15, where the device is a two-terminal device.

Example 17 provides the device of any of examples 14-16, where the device further includes a gate electrically coupled to the p-type region and the n-type region.

Example 18 provides a method including cooling an integrated circuit (IC) device to a temperature below 200 Kelvin, the IC device including a tunnel diode; and applying an input voltage to the tunnel diode, where the input voltage biases the tunnel diode in a negative differential resistance region of the tunnel diode, and the tunnel diode produces an oscillating output signal in response to the input voltage.

Example 19 provides the method of example 18, where the tunnel diode includes an n-type region and a p-type region, and at least one of the n-type region and the p-type region is degenerately doped.

Example 20 provides the method of example 19, where at least one of the n-type region and the p-type region includes a material having a band gap of less than 0.5 electronvolts (eV).

Example 21 provides an IC package that includes an IC die, including one or more of the IC devices according to any one of the preceding examples. The IC package may also include a further component, coupled to the IC die.

Example 22 provides the IC package according to example 21, where the further component is one of a package substrate, a flexible substrate, or an interposer.

Example 23 provides the IC package according to examples 21 or 22, where the further component is coupled to the IC die via one or more first level interconnects.

Example 24 provides the IC package according to example 23, where the one or more first level interconnects include one or more solder bumps, solder posts, or bond wires.

Example 25 provides a computing device that includes a circuit board; and an IC die coupled to the circuit board, where the IC die includes one or more of the transistor/IC devices according to any one of the preceding examples (e.g., transistor/IC devices according to any one of examples 1-20), and/or the IC die is included in the IC package according to any one of the preceding examples (e.g., the IC package according to any one of examples 21-24).

Example 26 provides the computing device according to example 25, where the computing device is a wearable computing device (e.g., a smart watch) or hand-held computing device (e.g., a mobile phone).

Example 27 provides the computing device according to examples 25 or 26, where the computing device is a server processor.

Example 28 provides the computing device according to examples 25 or 26, where the computing device is a motherboard.

Example 29 provides the computing device according to any one of examples 25-28, where the computing device further includes one or more communication chips and an antenna.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

What is claimed is:

1. A system comprising:
a cooling device; and
an integrated circuit (IC) device including a diode, the diode comprising:
an n-type region having a first dopant concentration greater than 10¹⁸ cm⁻³; and
a p-type region coupled to the n-type region, the p-type region having a second dopant concentration greater than 10¹⁸ cm⁻³.

2. The system of claim 1, wherein the cooling device comprises a direct refrigerant.

3. The system of claim 1, wherein the cooling device comprises a heat exchanger.

4. The system of claim 1, wherein the cooling device is on a cooling package, and the IC device is on a separate package from the cooling package.

5. The system of claim 1, wherein the cooling device is configured to cool the IC device to a temperature of 77-250 Kelvin.

6. The system of claim 1, wherein at least one of the n-type region and the p-type region comprises a material having a band gap of less than 0.5 electronvolts (eV).

7. The system of claim 6, wherein materials in the n-type region and the p-type region each have a band gap of less than 0.5 electronvolts (eV).

8. The system of claim 1, wherein the first dopant concentration is within an order of magnitude of the second dopant concentration.

9. The system of claim 1, wherein the n-type region comprises indium.

10. The system of claim 9, wherein the n-type region further comprises one of oxygen, nitrogen, or arsenic.

11. The system of claim 1, wherein the n-type region or the p-type region comprises tin.

12. The system of claim 11, wherein the n-type region or the p-type region further comprises one of oxygen, nitrogen, or arsenic.

13. The system of claim 1, wherein the n-type region or the p-type region comprises arsenic and one of titanium or tantalum.

14. A device comprising:
an n-type region having a first dopant concentration greater than 10¹⁸ cm⁻³; and
a p-type region coupled to the n-type region, the p-type region having a second dopant concentration greater than 10¹⁸ cm⁻³;
wherein at least one of the n-type region and the p-type region comprises a material having a band gap of less than 0.5 electronvolts (eV).

15. The device of claim 14, the device comprising a depletion region at a junction of the n-type region and the p-type region, wherein the n-type region and the p-type region form a semiconductor region having a first thickness, and the depletion region has a second thickness no more than 50% the first thickness.

16. The device of claim 14, wherein the device is a two-terminal device.

17. The device of claim 14, wherein the device further comprises a gate electrically coupled to the p-type region and the n-type region.

18. A method comprising:
cooling an integrated circuit (IC) device to a temperature below 200 Kelvin, the IC device comprising a tunnel diode; and
applying an input voltage to the tunnel diode, wherein the input voltage biases the tunnel diode in a negative differential resistance region of the tunnel diode, and the tunnel diode produces an oscillating output signal in response to the input voltage.

19. The method of claim 18, wherein the tunnel diode comprises an n-type region and a p-type region, and at least one of the n-type region and the p-type region is degenerately doped.

20. The method of claim 19, wherein at least one of the n-type region and the p-type region comprises a material having a band gap of less than 0.5 electronvolts (eV).
